(19) United States
(12) Patent Application Publication
(10) Pub. No.: US 2023/0212403 A1
(43) Pub. Date: Jul. 6, 2023

(54) NANOCRYSTALLINE AND MESOPOROUS ANATASE TiO2 FILMS COMPOSITION AND ITS SYNTHESIZING PROCESS THEREOF

(71) Applicants: Mohd. Shkir, Abha (SA); King Khalid University, Abha (SA)

(72) Inventors: Shoyebmohamad F. Shaikh, Riyadh (SA); Sharifah Mohammed Ali Al-Moayid, Abha (SA); Balaji G. Ghule, Nanded (IN); Mohd. Shkir, Abha (SA); Haitham Elhosiny Ali, Abha (SA); Hamed Majdooa Algarni, Abha (SA); Mohd Ubaidullah, Riyadh (SA); Rajaram S. Mane, Nanded (IN)

(21) Appl. No.: 18/175,920

(22) Filed: Feb. 28, 2023

(51) Int. Cl. C09D 1/00; C01G 23/053; C09D 7/63; H10K 30/50; H01G 9/20; H01G 9/00; H01G 11/46; H01G 11/86; C23C 18/12; C23C 14/18; C23C 14/24; G01N 27/48

(52) U.S. Cl. CPC C09D 1/00; C01G 23/0536; C09D 7/63; H10K 30/50; H01G 9/2031; H01G 9/0029; H01G 11/46; H01G 11/86; C23C 18/1216; C23C 14/18; C23C 14/24; G01N 27/48

(57) ABSTRACT

The process comprises treating 90-190 g titanium (IV) chloride in 10-100 ml de-ionized water for preparing Titanium cation (Ti⁴⁺); treating 130-275 ml potassium persulfate in 10-100 ml double-distilled water and keeping at constant temperature to obtain sulphate/oxide; dipping substrates into titanium (IV) chloride solution and re-dipping in de-ionized water to remove loosely bonded ions, if could be any; dipping substrates into potassium persulfate solution and re-dipping in de-ionized water to remove loosely bonded ions, if could be any, and keeping at 50-90° C. for complete one cycle; treating obtained Titanium cation (Ti⁴⁺) with sulphate/oxide and obtaining whitish layer on the substrate surface by necked eyes after about 10-15 cycles, suggesting initiation of film formation, wherein the deposition thickness of TiO₂ layer is increased from 0.3-2.0-micron on determined 5-50 deposition cycles; and rinsing deposited films with de-ionized water and air annealed at 400-600° C. temperature to obtain anatase TiO₂.

### RESEARCH FUNDING STATEMENT

This research was funded by Research Center for Advanced Materials Science (RCAMS), King Khalid University, Saudi Arabia, under grant number KKU/RCAMS/0021-23.

### FIELD OF THE INVENTION

The present disclosure relates to an ionic adsorption and reaction low-temperature chemical process for nanocrystalline, semiconducting, hydrophilic, and mesoporous anatase titanium oxide (TiO₂) thin films on conducting/non-conducting substrates for perovskite solar cell, gas sensor, electrochemical supercapacitor, and catalysis applications.

### BACKGROUND OF THE INVENTION

Due to their unique electrical, optical, thermal, chemical, and mechanical properties, transition metal oxides have drawn a lot of attention in scientific community. Titanium dioxide (TiO₂) is one of the transition metal oxides that deserves special attention due to its low cost, non-toxicity, diverse morphologies, stability in both acidic and alkaline media, different crystallographic forms, wide band-gap energy for various applications. In particular, titanium dioxide (TiO₂), which is a 3d transition metal oxide with different parity of electrons in the valence and conduction bands (hybridization of oxygen 2p states with titanium 3p states in the valence band and pure 3d states in the conduction band), has been found to be particularly useful. The three most well-known crystal structures of titanium dioxide are called rutile, anatase, and brookite, and the novelty of each lattice structure results in a wide variety of physicochemical and optoelectronic properties. These properties yield different functionalities and thereby influencing their performance in applications where they are applied. For instance, rutile TiO₂ exhibits a high refractive index high UV absorptivity and is, thus, capable of being used in optical communication devices like isolators, modulators, and switches, etc. Meanwhile, anatase is preferred mainly in photovoltaic and photocatalysis applications because of its superior electron mobility and catalytic activity compared to the other two phases i.e., rutile and brookite.

Several chemical methods like spray-pyrolysis, sol-gel, electro-spun, wet-chemical, electrodeposition, magnetron sputtering, and chemical vapor deposition, etc., have been envisaged to synthesize the TiO₂ nanocrystalline films/powders comprising nanowires, nanotubes, nanorods, and hollow microspheres, etc., morphologies which are either time consuming or operated at higher temperatures ((≥100° C.) with complicated processing steps and lack of clarity in the roles of some of the synthetic steps involved therein. Anatase TiO₂ has several applications in solar cells, energy storage, gas sensors, catalysis, etc., whose low-temperature and direct synthesis in nanocrystalline film form on conducting/non-conducting substrate are scare and challenging too.

In the view of the forgoing discussion, it is clearly portrayed that there is a need to have a nanocrystalline and mesoporous anatase TIO₂ films composition and its synthesizing process.

### SUMMARY OF THE INVENTION

The present disclosure seeks to provide a nanocrystalline and mesoporous anatase TIO₂ films composition and an ionic adsorption and reaction low-temperature chemical process using successive ionic layer adsorption and reaction (SILAR) for the conducting/non-conducting substrates applicable in perovskite solar cell, gas sensor, electrochemical supercapacitor, and catalysis applications. The anatase TiO₂ film as an electron transfer layer has evidenced a 9-12% power conversion efficiency of perovskite solar cells. Furthermore, room-temperature (25-30° C.) ammonia sensing measurement of the anatase TiO₂ film demonstrates various volatile organic compounds viz. ammonia, petrol, formaldehyde, ethanol, and acetone, with response and recovery time values for ammonia sensing are 20-40 and 80-100 s and 10-30 days stability. The anatase TiO₂ film on electrically conducting substrate envisaged in cyclic-voltammetry measurement in −0.2-0.8 V potential range at a constant sweep rate of 5-25 mV s⁻¹ with specific capacitance is 15-17 F/g in 1-6 M NaOH electrolyte. Furthermore, TiO₂ film powder acts as a catalyst in a three-component reaction of chromene derivative with ≥90% product yield, a short reaction time (3-6 h) using ethanol as a solvent, and 1-10 times reusability.

In an embodiment, a nanocrystalline and mesoporous anatase TiO₂ films composition is disclosed. The composition includes a powder extract of titanium (IV) chloride, from 90-190 g, in 10-100 ml de-ionized water; a powder extract of potassium persulfate, from 130-275 g, in 10-100 ml double-distilled water; a powder extract of Lead(II) iodide (PbI₂), from 200-600 mg, in N-N-dimethylformamide; a powder extract of methylammonium iodide, from 10-15 mg, in isopropanol; an aqueous extract of 4-tert-butyl pyridine, from 20-30 μl, in 1-2 ml of acetonitrile; and an aqueous extract of lithium bis(trifluoromethanesulfonyl)imide, from 10-20 μl, in 1-2 ml of acetonitrile.

In another embodiment, an adsorption and reaction chemical process for synthesizing nanocrystalline and mesoporous anatase TiO₂ films is disclosed. The process includes treating 90-190 g titanium (IV) chloride in 10-100 ml de-ionized water for preparing Titanium cation (Ti⁴⁺) in a first beaker. The process further includes treating 130-275 ml potassium persulfate in 10-100 ml double-distilled water in a second beaker and keeping at 50-90° C. constant temperature to obtain sulphate/oxide. The process further includes dipping conducting/non-conducting substrates into the titanium (IV) chloride solution for 20-30 s and re-dipping in de-ionized water for 10-20 s to remove loosely bonded ions, if could be any. The process further includes dipping conducting/non-conducting substrates into the potassium persulfate solution for 20-30 s and re-dipping in de-ionized water for 10-20 s to remove loosely bonded ions, if could be any, and keeping at 50-90° C. for complete one growth cycle. The process further includes treating obtained Titanium cation (Ti⁴⁺) with sulphate/oxide and obtaining whitish layer on the substrate surface by necked eyes after about 10-15 cycles, suggesting initiation of the film formation, wherein the deposition thickness of the TiO₂ layer is increased from 0.3-2.0-micron on determined 5-50 deposition cycles. The process further includes rinsing the deposited films with de-ionized water and air annealed at 400-600° C. temperature for 1 h to obtain anatase TiO₂.

An object of the present disclosure is to synthesize the anatase TiO₂ films of adherent, scalable, mesoporous, nanocrystalline, hydrophilic, semiconducting, and optically transparent characteristics.

Another object of the present disclosure is to use TiO₂ films for perovskite solar cells, gas sensors, electrochemical supercapacitors, and catalysis applications.

Yet another object of the present invention is to deliver an expeditious and cost-effective nanocrystalline and mesoporous anatase TIO₂ films composition.

To further clarify advantages and features of the present disclosure, a more particular description of the invention will be rendered by reference to specific embodiments thereof, which is illustrated in the appended drawings. It is appreciated that these drawings depict only typical embodiments of the invention and are therefore not to be considered limiting of its scope. The invention will be described and explained with additional specificity and detail with the accompanying drawings.

### BRIEF DESCRIPTION OF FIGURES

These and other features, aspects, and advantages of the present disclosure will become better understood when the following detailed description is read with reference to the accompanying drawings in which like characters represent like parts throughout the drawings, wherein:

FIG. 1 illustrates an adsorption and reaction chemical process for synthesizing nanocrystalline and mesoporous anatase TiO₂ films in accordance with an embodiment of the present disclosure;

FIG. 2 illustrates a) X-ray diffraction, b) Raman spectroscopy, c) Binding energy (survey) photoemission spectroscopy, d) UV-Vis absorbance spectrum (inset Tauc plot presenting the band-gap position) measurements of anatase TiO₂ in accordance with an embodiment of the present disclosure;

FIG. 3 illustrates a) Schematic diagram of perovskite solar cell device based on fluorine-tin-oxide/TiO₂/perovskite/spiro-OMeTAD/gold device in accordance with an embodiment of the present disclosure;

FIG. 4 illustrates schematic view of the gas sensor set-up used while anatase TiO₂ film sensor in accordance with an embodiment of the present disclosure;

FIG. 5 illustrates a) Cyclic-voltammetry (extended potential window −0.2 to −0.8 V at 5-50 mV s⁻¹ scan rates), b) Galvanostatic charge-discharge measurements at different current densities, and c) Specific capacitance vs. scan rate of SILAR-mediated anatase TiO₂ film in accordance with an embodiment of the present disclosure; and

FIG. 6 illustrates synthesis of chromene derivative in accordance with an embodiment of the present disclosure.

Further, skilled artisans will appreciate that elements in the drawings are illustrated for simplicity and may not have necessarily been drawn to scale. For example, the flow charts illustrate the method in terms of the most prominent steps involved to help to improve understanding of aspects of the present disclosure. Furthermore, in terms of the construction of the device, one or more components of the device may have been represented in the drawings by conventional symbols, and the drawings may show only those specific details that are pertinent to understanding the embodiments of the present disclosure so as not to obscure the drawings with details that will be readily apparent to those of ordinary skill in the art having benefit of the description herein.

### DETAILED DESCRIPTION

For the purpose of promoting an understanding of the principles of the invention, reference will now be made to the embodiment illustrated in the drawings and specific language will be used to describe the same. It will nevertheless be understood that no limitation of the scope of the invention is thereby intended, such alterations and further modifications in the illustrated system, and such further applications of the principles of the invention as illustrated therein being contemplated as would normally occur to one skilled in the art to which the invention relates.

It will be understood by those skilled in the art that the foregoing general description and the following detailed description are exemplary and explanatory of the invention and are not intended to be restrictive thereof.

Reference throughout this specification to “an aspect”, “another aspect” or similar language means that a particular feature, structure, or characteristic described in connection with the embodiment is included in at least one embodiment of the present disclosure. Thus, appearances of the phrase “in an embodiment”, “in another embodiment” and similar language throughout this specification may, but do not necessarily, all refer to the same embodiment.

The terms “comprises”, “comprising”, or any other variations thereof, are intended to cover a non-exclusive inclusion, such that a process or method that comprises a list of steps does not include only those steps but may include other steps not expressly listed or inherent to such process or method. Similarly, one or more devices or sub-systems or elements or structures or components proceeded by “comprises . . . a” does not, without more constraints, preclude the existence of other devices or other sub-systems or other elements or other structures or other components or additional devices or additional sub-systems or additional elements or additional structures or additional components.

Unless otherwise defined, all technical and scientific terms used herein have the same meaning as commonly understood by one of ordinary skill in the art to which this invention belongs. The system, methods, and examples provided herein are illustrative only and not intended to be limiting.

Embodiments of the present disclosure will be described below in detail with reference to the accompanying drawings.

In an embodiment, a nanocrystalline and mesoporous anatase TiO₂ films composition is disclosed. The composition includes a powder extract of titanium (IV) chloride, from 90-190 g, in 10-100 ml de-ionized water; a powder extract of potassium persulfate, from 130-275 g, in 10-100 ml double-distilled water; a powder extract of Lead(II) iodide (PbI₂), from 200-600 mg, in N-N-dimethylformamide; a powder extract of methylammonium iodide, from 10-15 mg, in isopropanol; an aqueous extract of 4-tert-butyl pyridine, from 20-30 μl, in 1-2 ml of acetonitrile; and an aqueous extract of lithium bis(trifluoromethanesulfonyl)imide, from 10-20 μl, in 1-2 ml of acetonitrile.

In another embodiment, molecular weight of titanium (IV) chloride and 0.5-1 M potassium persulfate is preferably 0.1-1 M and 0.5-1 M respectively.

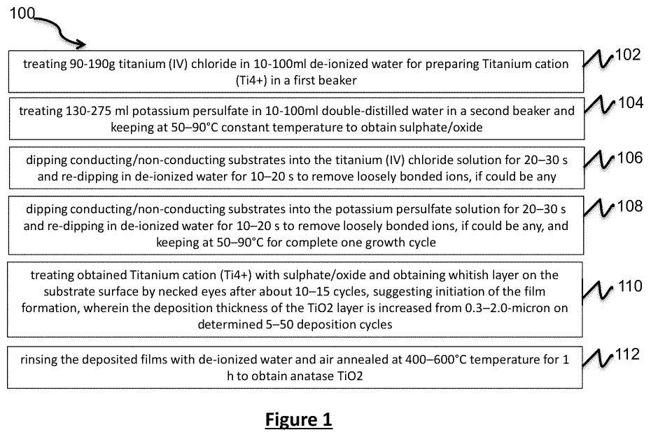

Referring to FIG. 1, an adsorption and reaction chemical process for synthesizing nanocrystalline and mesoporous anatase TiO₂ films is illustrated in accordance with an embodiment of the present disclosure. At step 102, the process 100 includes treating 90-190 g titanium (IV) chloride in 10-100 ml de-ionized water for preparing Titanium cation (Ti⁴⁺) in a first beaker.

At step 104, the process 100 includes treating 130-275 ml potassium persulfate in 10-100 ml double-distilled water in a second beaker and keeping at 50-90° C. constant temperature to obtain sulphate/oxide.

At step 106, the process 100 includes dipping conducting/non-conducting substrates into the titanium (IV) chloride solution for 20-30 s and re-dipping in de-ionized water for 10-20 s to remove loosely bonded ions, if could be any.

At step 108, the process 100 includes dipping conducting/non-conducting substrates into the potassium persulfate solution for 20-30 s and re-dipping in de-ionized water for 10-20 s to remove loosely bonded ions, if could be any, and keeping at 50-90° C. for complete one growth cycle.

At step 110, the process 100 includes treating obtained Titanium cation (Ti⁴⁺) with sulphate/oxide and obtaining whitish layer on the substrate surface by necked eyes after about 10-15 cycles, suggesting initiation of the film formation, wherein the deposition thickness of the TiO₂ layer is increased from 0.3-2.0-micron on determined 5-50 deposition cycles.

At step 112, the process 100 includes rinsing the deposited films with de-ionized water and air annealed at 400-600° C. temperature for 1 h to obtain anatase TiO₂.

In another embodiment, synthesis of nanocrystalline and mesoporous anatase TiO₂ films onto a conducting/non-conducting substrate like fluorine-tin-oxide, soda-lime glass, and stainless-steel, is corroborated by using a low-temperature (50-90° C.) SILAR-based chemical deposition process.

In another embodiment, deposition of SILAR-based anatase TiO₂ preferably of thickness 100-150 nm on conducting fluorine-tin-oxide substrate for perovskite solar cell device comprises dissolving PbI₂ in N-N-dimethylformamide at a concentration of 200-600 mg/ml under stirring at 50-80° C., wherein the solution is kept at 60-70° C. during the deposition procedure. Then, spin-coating the PbI₂ precursor on SILAR-based anatase TiO₂ film as an electron transfer layer at 2000-4000 rpm for 30-40 s and drying at 60-70° C. for 10-20 min. Then, dipping the films in a solution of methylammonium iodide in isopropanol preferably of 10-15 mg per ml for 20-30 s and rinsing with isopropanol, and drying by nitrogen gas after cooling to room temperature selected from 25-30° C. Then, spin-coating a volume of 60-80 μl spiro-OMeTAD solutions on the perovskite/TiO₂ layer at 2000-4000 rpm for 30-40 s. Then, depositing 60-100 nm of gold at 10⁻⁶-10⁻⁷ bar via thermal evaporation on the spiro-OMeTAD for electrical contacts forming a solar cell device with the fluorine-tin-oxide/TiO₂/perovskite/spiro-OMeTAD/gold configuration.

In another embodiment, the spiro-OMeTAD solutions are prepared by dissolving 60-80 mg spiro-OMeTAD in 1-2 ml of chlorobenzene, to which 20-30 μl of 4-tert-butyl pyridine and 10-20 μl of lithium bis(trifluoromethanesulfonyl)imide solution (400-600 mg Li-TFSI in 1-2 ml of acetonitrile) is added.

In another embodiment, 10-50 cycle operation results in the formation of anatase TiO₂ in 0.3-2.0-micron thickness which is adherent to the conducting/non-conducting substrate surface.

In another embodiment, anatase TiO₂ film sensor on soda-lime glass is selective to ammonia gas at room temperature (25-30° C.) among various volatile organic compounds viz. ammonia, petrol, formaldehyde, ethanol, and acetone, etc., with response and recovery time values of 20-40 and 80-100 s, respectively, in addition to, 10-30 days operation stability.

In another embodiment, estimating electrochemical supercapacitor performance comprises performing electrochemical supercapacitors tests using Potentiostat/Galvanostat controlled by electrolyzing workstation linked to a computer, wherein a one-compartment cell in 1-6 M NaOH using a three-electrode configuration on an Ivium instrument is used. Then, taking active anatase TiO₂ film mass on the stainless still substrate of 1-3 mg/cm², wherein the anatase TiO₂ film is the working electrode with Ag/AgCl as reference and platinum as the counter electrode. Then, envisaging the anatase TiO₂ film on stainless-steel substrate in cyclic-voltammetry measurement in −0.2-0.8 V potential range at a constant sweep rate of 5-25 mV s⁻¹.

In another embodiment, anatase TiO₂ film powder acts as catalysis in a three-component reaction of chromene derivative with ≥90% product yield, a short reaction time of 3-6 h using ethanol as a solvent, and 1-10 times reusability.

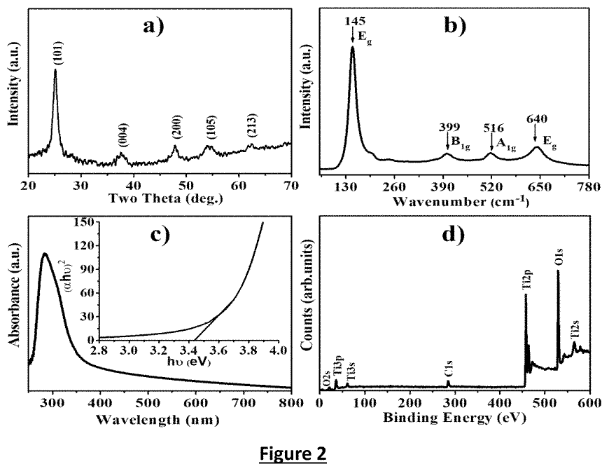

FIG. 2 illustrates a) X-ray diffraction, b) Raman spectroscopy, c) Binding energy (survey) photoemission spectroscopy, d) UV-Vis absorbance spectrum (inset Tauc plot presenting the band-gap position) measurements of anatase TiO₂ in accordance with an embodiment of the present disclosure. The X-ray diffraction pattern of 1-50 cycle TiO₂ film grown onto the soda-lime glass substrate of 0.3-2.0-micron thickness is shown in FIG. 2(a), where well-defined reflections of tetragonal crystal structure for anatase TiO₂ (JCPDS card no. 21-1272) are evidenced. No other impurity/phase reflection peak is obtained, suggesting high phase purity of the synthesized film. Grain size, dislocation density, and texture coefficient determined from the XRD pattern of TiO₂ are 10-12 nm, 12-18, and 2-4. The Raman spectroscopy of anatase TiO₂ film (FIG. 2(b) confirms a tetragonal space group D₄ₜₕ (I41/amd) with six Raman active modes (1A_{1g}+2B_{1g}+3E_{g}). The Raman peaks located at 143 (E_{g}), 199 (E_{g}), 396 (B_{1g}), 514 (A_{1g}), and 636 cm⁻¹ (E_{g}) are assigned to the anatase TiO₂. The X-ray photoelectron spectroscopy survey spectrum of the TiO₂ demonstrates Ti, O, and C core level photoemissions where the carbon peak at 284.8 eV is due to the residual and adventitious carbon. The core-level emissions at binding energies of 458.9 and 464.6 eV are of Ti2_{p3/2} and Ti2_{p1/2}, respectively. The peak with a binding energy of 530 eV is from O1ₛ, confirming the presence of oxygen anion in the lattice (Ti—C—Ti). The adsorption-desorption provides 100-150 m²/g specific surface area and 3-20 nm average pore size, endowing mesoporous character of the anatase TiO₂. The optical absorption studies where the band-gap, estimated within 100-850 nm wavelength range for anatase TiO₂ film at room temperature (25-30° C.) using UV-Vis spectrophotometer (V-530, Jasco, Oklahoma City, Okla., USA), when absorbance edge at around 350-450 nm with is confirmed 3.0-3.4 eV band gap energy and 70-85% transparency in the visible range. The surface wettability is a function of the interfacial tensions and determines the contact angle between water droplets on the film surface. The concept of complete wetting and non-wetting is based on the 0 and 180° contact angles, respectively. The water lies flat with a contact angle of 10-20° on the film surface, suggesting the hydrophilic nature of the anatase TiO₂ film surface.

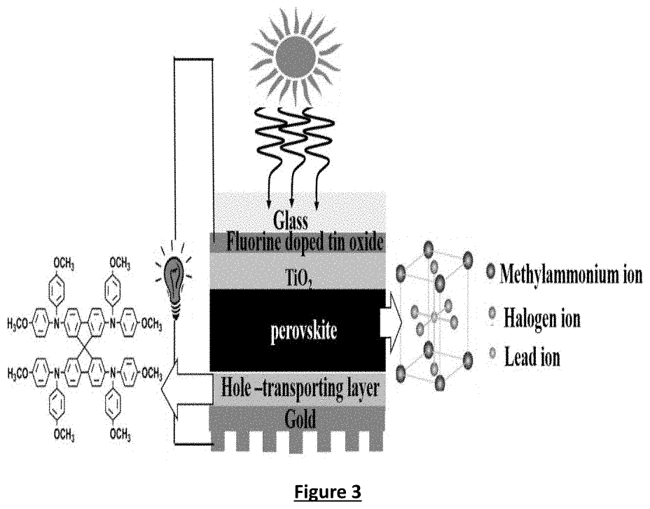

FIG. 3 illustrates a) Schematic diagram of perovskite solar cell device based on fluorine-tin-oxide/TiO₂/perovskite/spiro-OMeTAD/gold device in accordance with an embodiment of the present disclosure. The perovskite solar cell device where the deposition of SILAR-based anatase TiO₂ (thickness 100-150 nm) on conducting fluorine-tin-oxide substrate is performed. A perovskite absorber layer is directly applied through a two-step deposition method. Firstly, PbI₂ is dissolved in N-N-dimethylformamide at a concentration of 200-600 mg/ml under stirring at 50-80° C. The solution is kept at 60-70° C. during the deposition procedure. The PbI₂ precursor is spin-coated on SILAR-based anatase TiO₂ film as an electron transfer layer at 2000-4000 rpm for 30-40 s and dried at 60-70° C. for 10-20 min. Secondly, after cooling to room temperature (25-30° C.), the films are dipped in a solution of methylammonium iodide in isopropanol (10-15 mg per ml) for 20-30 s, rinsed with isopropanol, and dried by nitrogen gas. A volume of 60-80μl spiro-OMeTAD solutions is spin-coated on the perovskite/TiO₂ layer at 2000-4000 rpm for 30-40 s. The solution is prepared by dissolving 60-80 mg spiro-OMeTAD in 1-2 ml of chlorobenzene, to which 20-30 μl of 4-tert-butyl pyridine and 10-20 μl of lithium bis(trifluoromethanesulfonyl)imide solution (400-600 mg Li-TFSI in 1-2 ml of acetonitrile) is added. Finally, 60-100 nm of gold is deposited at 10⁻⁶-10⁻⁷ bar via thermal evaporation on the spiro-OMeTAD for electrical contacts forming a solar cell device with the fluorine-tin-oxide/TiO₂/perovskite/spiro-OMeTAD/gold configuration. The perovskite solar cells, tested under the illumination of simulated AM1.5 G simulated solar light (100 mW cm⁻²), with the TiO₂ film as an electron transfer layer, exhibit perovskite solar cell performance with an open circuit voltage of 0.6-0.9 V, short-open circuit voltage of 16-19 mA cm⁻¹, and power conversion efficiency of 6-12%.

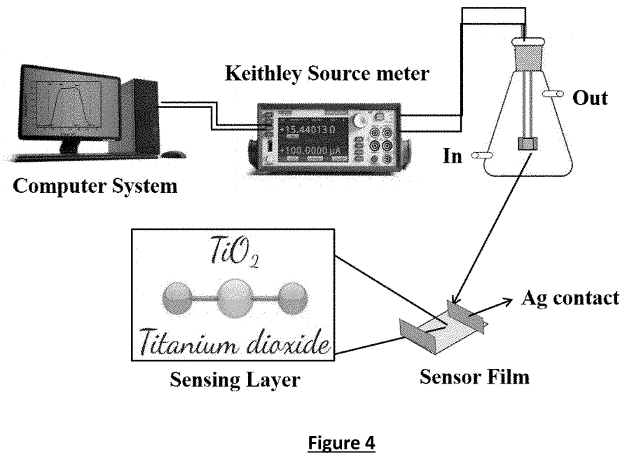

FIG. 4 illustrates schematic view of the gas sensor set-up used while anatase TiO₂ film sensor in accordance with an embodiment of the present disclosure. The gas sensing mechanism is based on alteration in the resistance of the sensing material, which is influenced by the adsorption-desorption process of target gas molecules via charge transfer processes. A schematic illustration of the sensor measurement system and gas sensing experimental set-up. The gas sensor unit consists of a conical glass cylindrical chamber with 200-300 ml volume capacity. The change in resistance of the sensor is recorded by using a computer-assisted 6-digit Keithley 6514 System Electrometer. The Keithley electrometer is coupled to the computer via RS232 interface to record the change in resistance with respect to time. For gas sensor studies, a sensor film of 1.5 cm×1.0 cm area was prepared by mixing composite with polyethylene glycol used as a binder and pasted on well-cleaned soda-lime glass slides using the doctor-blade method. For electrical contacts (each of 0.25 cm width), silver paste on the sensor film, using a 0.1 cm brush, is applied. The gas sensing chamber is introduced with dry and hot air before exposure to target gases to avoid the effect of humidity on the sensor performance. The gas sensing activity of the anatase TiO₂ film is investigated by exposing it to various volatile organic compounds viz. ammonia, petrol, formaldehyde, ethanol, and acetone gases. The sensitivity study of SILAR-mediated anatase TiO₂ film sensor for 100 (±10) ppm gas concentration at room temperature (25-30° C.). The anatase TiO₂ film sensor (on soda-lime glass substrate) offers better sensitivity (80-90%) for ammonia over other target gases used. The ammonia gas response of the anatase TiO₂ film sensor as a function of operating temperature is investigated. The response time, recorded maximum at room temperature (25-30° C.) decreases with at higher temperatures. The transient ammonia response of the anatase TiO₂ film sensor. On exposing ammonia in the testing chamber; diffused ammonia molecules adsorb on the TiO₂ film sensor surface over time. The response and recovery time values of the TiO₂ film sensor for ammonia sensing are 20-40 and 80-100 s, respectively, signifying the use of the anatase TiO₂ film as a potential room-temperature (25-30° C.) ammonia sensor. The dynamic repeatability study of the TiO₂ film sensor is studied, revealing approximately the same ammonia response over a few cycles, which is an indication of the repeatable contribution of the TiO₂ film sensor. The ammonia response of the TiO₂ sensor studied for various concentrations at the room-temperature i.e., 25-30° C., endows the lowest ammonia detected limit of 1-4% for 5-10 ppm. The highest ammonia response for 800-1000 ppm concentration is 90-100%. For higher ammonia concentration, due to maximal coverage for the anatase TiO₂ film surface by ammonia molecules to the point, little resistance changes are detected, and the gas response saturates. The stability plot of the anatase TiO₂ film sensor for ammonia. The response stability of the TiO₂ film sensor towards 100-120 ppm concentrations of ammonia, studied for 15-30 days, is almost constant, suggesting the commercial potential of SILAR-processed anatase TiO₂ film gas sensor.

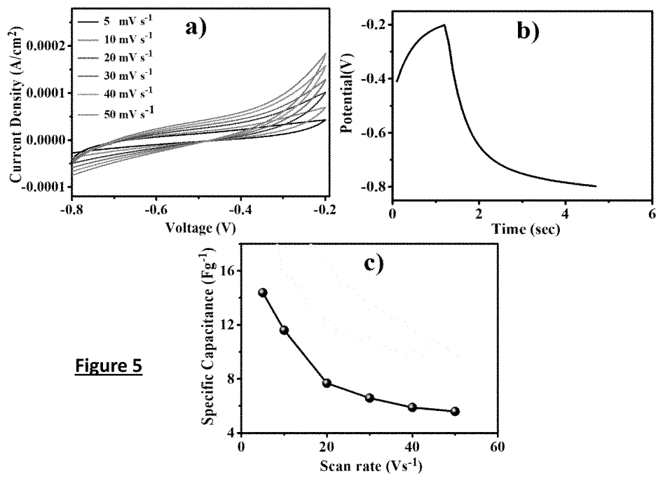

FIG. 5 illustrates a) Cyclic-voltammetry (extended potential window −0.2 to −0.8 V at 5-50 mV s⁻¹ scan rates), b) Galvanostatic charge-discharge measurements at different current densities, and c) Specific capacitance vs. scan rate of SILAR-mediated anatase TiO₂ film in accordance with an embodiment of the present disclosure.

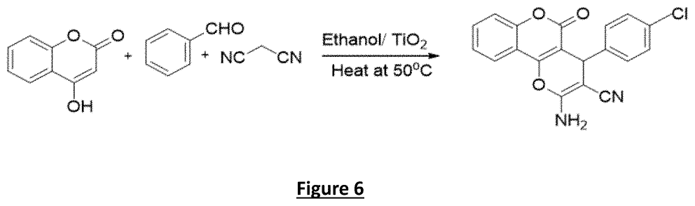

FIG. 6 illustrates synthesis of chromene derivative in accordance with an embodiment of the present disclosure. Synthesis of nanocrystalline and mesoporous anatase TiO₂ films onto a conducting/non-conducting substrate like fluorine-tin-oxide, soda-lime glass, and stainless-steel, is corroborated by using a low-temperature (50-90° C.) SILAR-based chemical deposition process. Briefly, 0.1-1 M titanium (IV) chloride (10-100 ml) is prepared in de-ionized water as the Ti⁴⁺ source in one beaker. In another beaker, 0.5-1M potassium persulfate is obtained in (10-100 ml) double-distilled water and kept at 50-90° C. constant temperature and used as sulphate/oxide source. The conducting/non-conducting substrates are dipped into the titanium (IV) chloride solution for 20-30 s; the same substrate is re-dipped in de-ionized water for 10-20 s to remove loosely bonded ions, if could be any. A similar procedure is performed in potassium persulfate solution, kept at 50-90° C. with the same substrate, for complete one growth cycle. After about 10-15 cycles, a whitish layer can be noticed on the substrate surface by necked eyes, suggesting initiation of the film formation. The deposition thickness of the TiO₂ layer is increased from 0.3-2.0-micron on determined 5-50 deposition cycles. The deposited films are rinsed with de-ionized water and air annealed at 400-600° C. temperature for 1 h to obtain anatase TiO₂, whose chemical reaction mechanism is as follows;

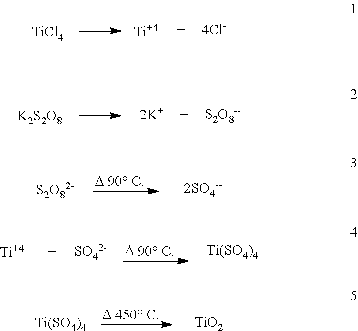

Electrochemical Supercapacitor Application:

A cyclic voltammogram and galvanostatic charge-discharge measurements are ideal for estimating electrochemical supercapacitor performance. The rectangular shape of cyclic voltammetry with a large magnitude of current density and symmetry in the anodic and cathodic directions are a few standards for ideal electrochemical supercapacitors.

Electrochemical supercapacitors tests are performed using Potentiostat/Galvanostat controlled by electrolyzing workstation linked to a computer. A one-compartment cell in 1-6 M NaOH using a three-electrode configuration on an Ivium (electrochemical compactstat) instrument is used. The active anatase TiO₂ film mass on the stainless still substrate is 1-3 mg/cm². The anatase TiO₂ film is the working electrode with Ag/AgCl as reference and platinum as the counter electrode. The anatase TiO₂ film on stainless-steel substrate is envisaged in cyclic-voltammetry measurement in −0.2-0.8 V potential range at a constant sweep rate of 5-25 mV s⁻¹. The specific capacitance value of TiO₂ electrode is 15-17 F/g, suggesting the energy storage potential of SILAR-mediated anatase TiO₂ film.

Catalytic Application of Chromene Derivatives:

The anatase TiO₂ is utilized to synthesize chromene derivatives as a catalyst. The catalytic activity of anatase TiO₂ has been evaluated for the synthesis of chromene derivatives in ethanol under mild thermal conditions, affording high yields (≥90%), of the desired products. The reaction of 4-hydroxycoumarin with 3-Chlorobenzaldehyde and malononitrile has been chosen as a model reaction for examining catalytic activity (FIG. 6). The reaction between 4-hydroxycoumarin, 3-bromobenzaldehyde, and malononitrile, along with the catalyst, has been performed. The present process is eco-friendly for synthesizing chromene derivatives with catalyst recyclability, a high yield of desired products (≥90%), and a short reaction time of 3-6 h in ethanol as a solvent.

A low-temperature chemical synthesis process based on the ionic adsorption and reaction principle so called, “successive ionic layer adsorption and reaction (SILAR)” for the synthesis of anatase nanocrystalline TiO2 film onto a conducting as well as non-conducting substrates is unveiled which is free from the use of high-quality target and/or substrate and vacuum systems; the deposition rate and the thickness followed optical density of the product nanocrystalline TiO2 film are controlled over a wide range by changing the deposition cycles; there are virtually no restrictions on the substrate materials, followed dimensions; moreover, it is convenient for a significant area deposition for commercial benefits. As synthesized SILAR-mediated anatase TiO2 films on conducting/non-conducting substrates are nanocrystalline, semiconducting, optically transparent, and mesoporous, suitable for perovskite solar cells, gas sensors, electrochemical supercapacitors, and catalysis applications.

An ionic adsorption and reaction low-temperature (50-90° C.) chemical process to synthesize the anatase TiO₂ films of adherent, scalable, mesoporous, nanocrystalline, hydrophilic, semiconducting, and optically transparent characteristics using 0.1-1 M titanium (IV) chloride and 0.5-1 M potassium persulfate precursor solutions (10-100 ml) on conducting/non-conducting substrate at room temperature (25-30° C.) for perovskite, gas sensor, supercapacitor, and catalysis applications.

Tetragonal crystal structure and anatase phase of TiO₂ is approved.

10-50 cycle operation results in the formation of anatase TiO₂ in 0.3-2.0-micron thickness which is adherent to the conducting/non-conducting substrate surface.

Non-conducting substrate like soda-lime glass and electrically conducting substrate, i.e., fluorine-tin-oxide coated glass and stainless-steel substrate, is used.

Anatase TiO₂ is coated on the conducting/non-conducting substrate area, i.e., 100-200 cm².

obtained TiO₂ film is phase pure, i.e., anatase, nanocrystalline with an average grain size of 3-20 nm, 70-85% optically transparent in the visible region, and hydrophilic with 10-20° surface water contact angle measurement.

Anatase TiO₂ powder is mesoporous with an average pore size of 3-20 nm and a specific surface area of 100-150 m²/g.

Anatase TiO₂ film prepared on conducting/non-conducting substrate is active in perovskite solar cells, gas sensors, supercapacitors, and catalysis applications.

A power conversion efficiency of perovskite solar cells using anatase TiO₂ film as electron transfer layer is 6-12%.

Anatase TiO₂ film sensor on soda-lime glass is selective to ammonia gas at room temperature (25-30° C.) among various volatile organic compounds viz. ammonia, petrol, formaldehyde, ethanol, and acetone, etc., with response and recovery time values of 20-40 and 80-100 s, respectively, in addition to, 10-30 days operation stability.

Anatase TiO₂ film on stainless steel within −0.2-0.8 V potential range at a constant sweep rate of 5-25 mV s⁻¹ demonstrate 15-17 F/g specific capacitance.

Anatase TiO₂ film powder acts as catalysis in a three-component reaction of chromene derivative with ≥90% product yield, a short reaction time of 3-6 h using ethanol as a solvent, and 1-10 times reusability.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

Benefits, other advantages, and solutions to problems have been described above with regard to specific embodiments. However, the benefits, advantages, solutions to problems, and any component(s) that may cause any benefit, advantage, or solution to occur or become more pronounced are not to be construed as a critical, required, or essential feature or component of any or all the claims.

Acknowledgment

The authors extend their appreciation to the Research Center for Advanced Materials Science (RCAMS), King Khalid University, Saudi Arabia, for funding this work under grant number KKU/RCAMS/0021-23.

1. A nanocrystalline and mesoporous anatase TiO₂ films composition comprising:
a powder extract of titanium (IV) chloride, from 90-190 g, in 10-100 ml de-ionized water;
a powder extract of potassium persulfate, from 130-275 g, in 10-100 ml double-distilled water;
a powder extract of Lead(II) iodide (PbI₂), from 200-600 mg, in N-N-dimethylformamide;
a powder extract of methylammonium iodide, from 10-15 mg, in isopropanol;
an aqueous extract of 4-tert-butyl pyridine, from 20-30 μl, in 1-2 ml of acetonitrile; and
an aqueous extract of lithium bis(trifluoromethanesulfonyl)imide, from 10-20 μl, in 1-2 ml of acetonitrile.

2. The composition as claimed in claim 1, wherein molecular weight of titanium (IV) chloride and 0.5-1 M potassium persulfate is preferably 0.1-1 M and 0.5-1 M respectively.

3. A process for synthesizing nanocrystalline and mesoporous anatase TiO₂ films, the process comprises:
treating 90-190 g titanium (IV) chloride in 10-100 ml de-ionized water for preparing Titanium cation (Ti⁴⁺) in a first beaker;
treating 130-275 ml potassium persulfate in 10-100 ml double-distilled water in a second beaker and keeping at 50-90° C. constant temperature to obtain sulphate/oxide;
dipping conducting/non-conducting substrates into the titanium (IV) chloride solution for 20-30 s and re-dipping in de-ionized water for 10-20 s to remove loosely bonded ions, if could be any;
dipping conducting/non-conducting substrates into the potassium persulfate solution for 20-30 s and re-dipping in de-ionized water for 10-20 s to remove loosely bonded ions, if could be any, and keeping at 50-90° C. for complete one growth cycle;
treating obtained Titanium cation (Ti⁴⁺) with sulphate/oxide and obtaining whitish layer on the substrate surface by necked eyes after about 10-15 cycles, suggesting initiation of the film formation, wherein the deposition thickness of the TiO₂ layer is increased from 0.3-2.0-micron on determined 5-50 deposition cycles; and
rinsing the deposited films with de-ionized water and air annealed at 400-600° C. temperature for 1 h to obtain anatase TiO₂.

4. The process as claimed in claim 3, wherein synthesis of nanocrystalline and mesoporous anatase TiO₂ films onto a conducting/non-conducting substrate like fluorine-tin-oxide, soda-lime glass, and stainless-steel, is corroborated by using a low-temperature (50-90° C.) SILAR-based chemical deposition process.

5. The process as claimed in claim 3, wherein deposition of SILAR-based anatase TiO₂ preferably of thickness 100-150 nm on conducting fluorine-tin-oxide substrate for perovskite solar cell device comprises:
dissolving PbI₂ in N-N-dimethylformamide at a concentration of 200-600 mg/ml under stirring at 50-80° C., wherein the solution is kept at 60-70° C. during the deposition procedure;
spin-coating the PbI₂ precursor on SILAR-based anatase TiO₂ film as an electron transfer layer at 2000-4000 rpm for 30-40 s and drying at 60-70° C. for 10-20 min;
dipping the films in a solution of methylammonium iodide in isopropanol preferably of 10-15 mg per ml for 20-30 s and rinsing with isopropanol, and drying by nitrogen gas after cooling to room temperature selected from 25-30° C.;
spin-coating a volume of 60-80 μl spiro-OMeTAD solutions on the perovskite/TiO₂ layer at 2000-4000 rpm for 30-40 s; and
depositing 60-100 nm of gold at 10⁻⁶-10⁻⁷ bar via thermal evaporation on the spiro-OMeTAD for electrical contacts forming a solar cell device with the fluorine-tin-oxide/TiO₂/perovskite/spiro-OMeTAD/gold configuration.

6. The process as claimed in claim 5, wherein the spiro-OMeTAD solutions are prepared by dissolving 60-80 mg spiro-OMeTAD in 1-2 ml of chlorobenzene, to which 20-30 μl of 4-tert-butyl pyridine and 10-20 μl of lithium bis(trifluoromethanesulfonyl)imide solution (400-600 mg Li-TFSI in 1-2 ml of acetonitrile) is added.

7. The process as claimed in claim 3, wherein 10-50 cycle operation results in the formation of anatase TiO₂ in 0.3-2.0-micron thickness which is adherent to the conducting/non-conducting substrate surface.

8. The process as claimed in claim 3, wherein anatase TiO₂ film sensor on soda-lime glass is selective to ammonia gas at room temperature (25-30° C.) among various volatile organic compounds viz. ammonia, petrol, formaldehyde, ethanol, and acetone, etc., with response and recovery time values of 20-40 and 80-100 s, respectively, in addition to, 10-30 days operation stability.

9. The process as claimed in claim 3, further comprising estimating electrochemical supercapacitor performance by:
performing electrochemical supercapacitors tests using Potentiostat/Galvanostat controlled by electrolyzing workstation linked to a computer, wherein a one-compartment cell in 1-6 M NaOH using a three-electrode configuration on an Ivium instrument is used;
taking active anatase TiO₂ film mass on the stainless still substrate of 1-3 mg/cm², wherein the anatase TiO₂ film is the working electrode with Ag/AgCl as reference and platinum as the counter electrode; and
envisaging the anatase TiO₂ film on stainless-steel substrate in cyclic-voltammetry measurement in −0.2-0.8 V potential range at a constant sweep rate of 5-25 mV s⁻¹.

10. The process as claimed in claim 3, wherein anatase TiO₂ film powder acts as catalysis in a three-component reaction of chromene derivative with ≥90% product yield, a short reaction time of 3-6 h using ethanol as a solvent, and 1-10 times reusability.
